(19) United States
(12) Patent Application Publication
(10) Pub. No.: US 2009/0194835 A1
(43) Pub. Date: Aug. 6, 2009

(54) IMAGE SENSOR

(76) Inventor: Byung-Jun Park, Yongin-si (KR)

Correspondence Address: F. CHAU & ASSOCIATES, LLC, 130 WOODBURY ROAD, WOODBURY, NY, 11797, US

(21) Appl. No.: 12/364,973

(22) Filed: Feb. 3, 2009

(30) Foreign Application Priority Data
Feb. 5, 2008 (KR) 10-2008-0011914

(51) Int. Cl. H01L 31/0256

(52) U.S. Cl. 257/459; 257/E31.003

(57) ABSTRACT

An image sensor capable of reducing crosstalk between pixels is provided. The image sensor includes a photoelectric converter formed in a semiconductor substrate, an interlayer insulating layer formed on the semiconductor substrate, a plurality of structures formed on the interlayer insulating layer, each of the plurality of structures including an insulating pillar, a metal interconnection formed on the insulating pillar, and a spacer formed at both sides of the metal interconnection and both sides of the insulating pillar. The plurality of structures are spaced a predetermined interval apart from each other in a longitudinal direction. The image sensor further includes an intermetal insulating layer filling spaces between the plurality of structures and covering top surfaces of the plurality of structures.

### CROSS-REFERENCE TO RELATED APPLICATION

This application claims priority from Korean Patent Application No. 10-2008-0011914 filed on Feb. 5, 2008, the disclosure of which is hereby incorporated by reference herein in its entirety.

### BACKGROUND OF THE INVENTION

1. Technical Field

The present disclosure relates to an image sensor, and more particularly, to an image sensor capable of reducing crosstalk between pixels.

2. Description of the Related Art

In general, image sensors may convert an optical image into an electrical signal. Recently, along with the advanced computer industry and the development of the communications industry, there has been increasing demand for image sensors with enhanced performance in a variety of fields, including digital cameras, camcorders, PCS (personal communication system), game devices, surveillance cameras, micro-cameras for medical use, and robots.

Each pixel of an image sensor may perform photoelectric conversion of incident light and accumulates a quantity of electrical charge in relation to an amount of light detected by the sensor to then reproduce an image signal by a read-out operation. However, the incident light may adversely affect neighboring elements rather than accumulating on a photoelectric converter of a pertinent unit pixel. In the case of a CCD (charge coupled device), for example, charges generated at lower or side portions of a photodiode may be induced into a channel of the CCD, causing a smearing phenomenon. In the case of a CMOS image sensor, charges may migrate to a photoelectric converter of a neighboring pixel and accumulate thereon, thereby causing pixel crosstalk.

The pixel crosstalk may propagate to a photoelectric converter of a neighboring unit pixel, instead of a corresponding unit pixel, due to the refracted light formed by refraction of the incident light, which has passed through a micro lens and/or a color filter, from the surface of a multi-layered structure composed of interlayer insulating layers having different refractive indices or the surface of a non-uniform film or a reflected light formed by reflection of a light from a top surface or a side surface of a metal interconnection.

Upon occurrence of the pixel crosstalk, a black/white image sensor may experience degradation of a resolution, thereby causing image artifacts. In the case of a color image sensor using a red-green-blue (RGB) color filter array (CFA), crosstalk is likely to occur due to a red incident light having a large wavelength, thereby resulting in a tint failure. Moreover, a blooming phenomenon may occur in which neighboring pixels on a screen blur.

### SUMMARY OF THE INVENTION

Exemplary embodiments of the present invention may provide an image sensor capable of reducing crosstalk between pixels.

In accordance with an exemplary embodiment of the present invention, an image sensor is provided. The image sensor includes a photoelectric converter formed in a semiconductor substrate, an interlayer insulating layer formed on the semiconductor substrate, a plurality of structures formed on the interlayer insulating layer, each of the plurality of structures including an insulating pillar, a metal interconnection formed on the insulating pillar, and a spacer formed at both sides of the metal interconnection and both sides of the insulating pillar. The plurality of structures are spaced a predetermined interval apart from each other in a longitudinal direction. The image sensor further includes an intermetal insulating layer filling spaces between the plurality of structures and covering top surfaces of the plurality of structures.

In accordance with an exemplary embodiment of the present invention, an image sensor is provided. The image sensor includes a photoelectric converter formed in a semiconductor substrate, an interlayer insulating layer formed on the semiconductor substrate, a plurality of first structures formed on the interlayer insulating layer, each of the plurality of first structures including a first insulating pillar protruding above the interlayer insulating layer, a first metal interconnection formed on the first insulating pillar, and a first spacer formed at both sides of the first metal interconnection and both sides of the first insulating pillar. The plurality of first structures are spaced a predetermined interval apart from each other in a transverse direction. The image sensor further includes an intermetal insulating layer formed on the interlayer insulating layer where the plurality of first structures are formed covering the interlayer insulating layer and the plurality of first structures, and a plurality of second structures formed on the interlayer insulating layer, each of the plurality of second structures including a second insulating pillar protruding above the intermetal insulating layer, a second metal interconnection formed on the second insulating pillar, and a second spacer formed at both sides of the second metal interconnection and both sides of the second insulating pillar, and wherein the plurality of second structures are spaced a predetermined interval apart from each other in a transverse direction.

In accordance with an exemplary embodiment of the present invention, an image sensor image sensor is provided. The image sensor includes a plurality of photoelectric converters that are formed adjacent to each other in a semiconductor substrate, and an insulating layer formed on the semiconductor substrate in such a way as to cover the semiconductor substrate. The insulating layer includes a plurality of recesses formed on at least a portion of each of the plurality of photoelectric converters. The image sensor further includes a metal interconnection formed on a top surface of the insulating layer defined between two neighboring recesses of the insulating layer, wherein both sides of the metal interconnection are formed aligned with sides of the two neighboring recesses, and a spacer formed at both sides of the metal interconnection and sides of the two recesses aligned with the both sides of the metal interconnection.

### BRIEF DESCRIPTION OF THE DRAWINGS

Exemplary embodiments of the present invention can be understood in further detail from the following description taken in conjunction with the attached drawings in which:

FIG. 1 is a block diagram of an image sensor according to an exemplary embodiment of the present invention;

FIG. 2 is a circuit diagram of a unit pixel of an image sensor according to an exemplary embodiment of the present invention;

FIG. 3 is a cross-sectional view of an image sensor according to an exemplary embodiment of the present invention;

FIGS. 4 through 10 are views for explaining a method of manufacturing an image sensor according to an exemplary embodiment of the present invention; and

FIG. 11 is a schematic diagram of a processor-based system including an image sensor according to an exemplary embodiment of the present invention.

### DETAILED DESCRIPTION OF THE EXEMPLARY EMBODIMENTS OF THE INVENTION

The present invention may, however, be embodied in many different forms and should not be construed as being limited to the exemplary embodiments set forth herein. Thus, in some exemplary embodiments, well-known processing steps are generally not described in detail to avoid unnecessarily obscuring the description of the present invention.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

It is noted that the use of any and all examples, or exemplary terms provided herein is intended merely to better illuminate the invention and is not a limitation on the scope of the invention unless otherwise specified. As used in the description of the invention and the appended claims, the singular forms “a”, “an” and “the” are intended to include the plural forms as well, unless the context clearly indicates otherwise. The terms “comprising” and “comprises” are to be construed as open-ended terms (i.e., meaning “including, but not limited to,”) to indicate any and all possible combinations of one or more of the associated components, steps, operations, and/or devices unless otherwise noted.

Spatially relative terms, such as “below”, “beneath”, “lower”, “above”, “upper” and the like, may be used herein for ease of description to describe one element or feature's relationship to another element(s) or feature(s) as illustrated in the figures. It will be understood that spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Image sensors according to exemplary embodiments of the present invention include a charge coupled device (CCD) image sensor and a complementary metal oxide semiconductor (CMOS) image sensor. The CDD image sensor has smaller noise and better image quality than the CMOS image sensor. However, the CCD image sensor may require a high voltage and may be expensive to manufacture. The CMOS image sensor may be easy to operate and can be implemented in various scanning methods. As a signal processing circuit can be integrated with the image sensor on a single chip, smaller products can be produced as a result. In addition, the manufacturing cost can be reduced using a CMOS manufacturing technology. Further, due to its very low power consumption, the CMOS image sensor can be easily applied to products with limited battery capacity. Due to the above benefits of the CMOS image sensor, the present invention will be described with reference to the CMOS image sensor. However, the technical spirit of exemplary embodiments of the present invention can also be applied to a CCD image sensor.

Hereinafter, exemplary embodiments of the present invention will be explained in more detail with reference to the accompanying drawings.

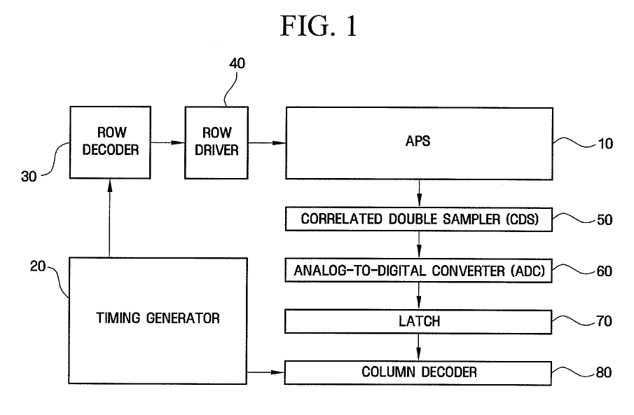

FIG. 1 is a block diagram of an image sensor according to an exemplary embodiment of the present invention.

Referring to FIG. 1, the image sensor 1 includes an active pixel sensor (APS) array 10, a timing generator 20, a row decoder 30, a row driver 40, a correlated double sampler (CDS) 50, an analog-to-digital converter (ADC) 60, a latch 70, and a column decoder 80.

The APS array 10 includes a plurality of unit pixels arranged in a matrix array. The plurality of unit pixels convert an optical image into an electrical signal. The APS array 10 operates in response to a plurality of driving signals such as a pixel selection signal (ROW), a reset signal (RST), and first and second charge transmission signals (TG1 and TG2) received from the row driver 40. The APS array 10 provides the electrical signal to the CDS 50 via a vertical signal line.

The timing generator 20 provides a timing signal and a control signal to the row decoder 30 and the column decoder 80.

The row driver 40 provides the plurality of driving signals to the APS array 10 to operate the plurality of unit pixels according to a decoding result of the row decoder 30. Generally, when the unit pixels are arranged in a matrix form, a driving signal is provided for each row. The CDS 50 receives the electrical signal from the APS array 10 via the vertical signal line and performs holding and sampling. For example , the CDS 50 double samples a reference voltage level (hereinafter, referred to as a “noise level”) and a voltage level of the electrical signal (hereinafter, referred to as a “signal level”) and outputs a differential level corresponding to a difference between the noise level and the signal level.

The ADC 60 converts an analog signal corresponding to the differential level into a digital signal.

The latch 70 latches the digital signal. The latched signal is sequentially output to an image signal processor according to a decoding result of the column decoder 80.

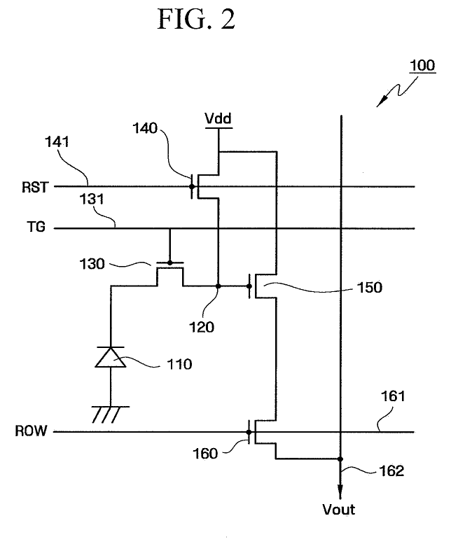

FIG. 2 is a circuit diagram of a unit pixel of an image sensor according to an exemplary embodiment of the present invention.

Referring to FIG. 2, a unit pixel 100 of the image sensor includes a photoelectric converter 110, a charge detector 120, a charge transfer unit 130, a reset unit 140, an amplifier 150, and/or a selector 160. Although the unit pixel 100 includes four transistor (4T) structures as illustrated in FIG. 2 in the current embodiment of the present invention, it may also include, for example, five transistor (5T) structures.

The photoelectric converter 110 absorbs an incident light and accumulates charges corresponding to the quantity of light. The photoelectric converter 110 may be, for example, a photodiode, a photo transistor, a photo gate, a PPD (pinned photodiode), or a combination thereof.

As an example, a floating diffusion region (FD) may be used as the charge detector 120. The charge detector 120 may receive the charge accumulated in the photoelectric transducer 110. The charge detector 120 may have parasitic capacitance and thus may accumulate the charge. The charge detector 120 may be electrically connected to a gate of the amplifier 150 and may control the amplifier 150.

The charge transfer unit 130 may transfer charge from the photoelectric transducer 110 to the charge detector 120. The charge transfer unit 130 may be composed of, for example, one transistor that may be controlled by a charge transfer signal TG.

The reset unit 140 may periodically reset the charge detector 120. A charge source of the reset unit 140 may be connected to the charge detector 140, and a charge drain thereof may be connected to a power supply Vdd. The reset unit 140 may be driven in response to a reset signal RST.

The amplifier 150 may act as a source follower buffer amplifier with a constant current source positioned outside the unit pixel 100 such that a voltage varying in response to the voltage of the charge detector 120 may be output to a vertical signal line 162. A charge source of the amplifier 150 may be connected to a charge drain of the selector 160 and a drain thereof is connected to the power supply Vdd.

The selector 160 may serve to select a row of unit pixels 100 to be read. The selector 160 may be driven in response to a selection signal ROW, and a source of the selector 160 may be connected to the vertical signal line 162.

Driving signal lines 131, 141, and/or 161 of the charge transfer unit 130, the reset unit 140, and/or the selector 160 may extend in a row direction (shown as horizontal in FIG. 1) such that the unit pixels of the same row may be simultaneously driven.

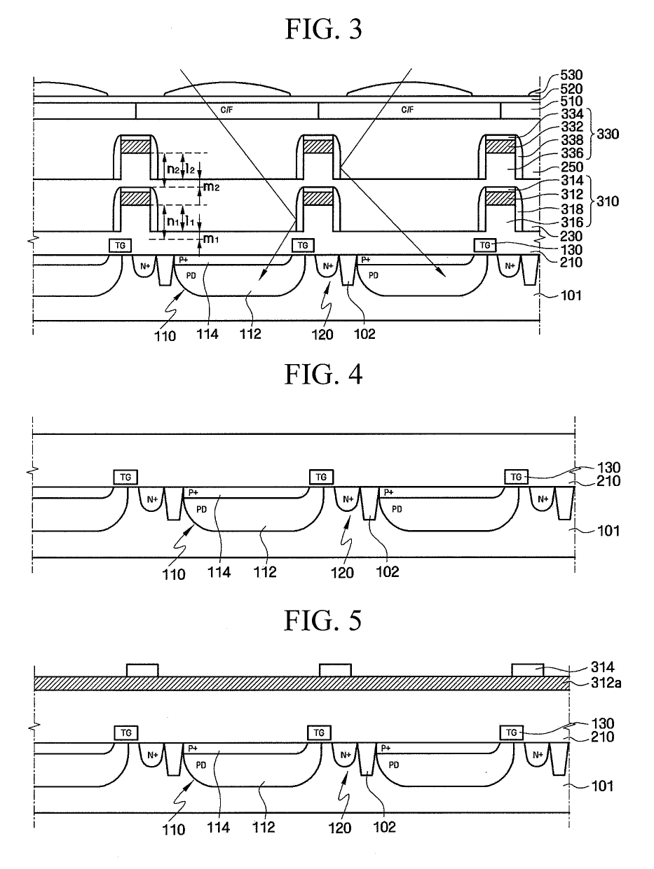

FIG. 3 is a cross-sectional view of an image sensor according to an exemplary embodiment of the present invention.

Referring to FIG. 3, the image sensor according to an exemplary embodiment of the present invention includes a semiconductor substrate 101 and a plurality of unit pixels formed in the semiconductor substrate 101. Each of the plurality of unit pixels includes the photoelectric converter 110, the charge detector 120, and the charge transfer unit 130.

The semiconductor substrate 101 may include various types of substrates. For example, a first conductivity type, e.g., an N-type substrate, may be used as the substrate 101. A device isolation region 102 may be formed in the semiconductor substrate 101 to define an active region. The device isolation layer 102 may be, for example, a field oxide (FOX) or shallow trench isolation (STI) region formed by a local oxidation of silicon (LOCOS) method. In addition, a depletion well of, for example, a second conductivity type, e.g., a P-type, may be formed below the device isolation layer 102.

The photoelectric converter 110 includes, for example, a P+-type pinning layer 112 and an N-type photodiode 114 formed in the semiconductor substrate 101.

The pinning layer 112 can be reduce or prevent by reducing EHPs (Electron-Hole Pairs) thermally generated from a surface of the substrate. Charges corresponding to the amount of incident light having each wavelength accumulate in the photodiode 114.

The charge detector 120, formed in the semiconductor substrate 101, receives the charges accumulated in the photoelectric converter 110 through the charge transfer unit 130. The charge transfer unit 130 may include a gate insulating layer, a gate electrode, and a spacer.

On the semiconductor substrate 101 where a plurality of unit pixels are formed, an interlayer insulating layer 210 is formed. The interlayer insulating layer 210 may be formed in such a way as to cover the plurality of unit pixels, e.g., the photoelectric converter 110, the charge transfer unit 130, and the charge detector 120, formed on the semiconductor substrate 101. The interlayer insulating layer 210 may be formed of, for example, High Density Plasma (HDP), Tonen SilaZene (TOSZ), Spin On Glass (SOG), or Undoped Silica Glass (USG).

A portion of the interlayer insulating layer 210 protrudes upwardly to form a first insulating pillar 316. The first insulating pillar 316 is formed in a periphery of the photoelectric converter 110, e.g., in a region between neighboring photoelectric converters 110. At this time, a plurality of first insulating pillars 316 protruding above the interlayer insulating layer 210 are formed, wherein a plurality of recesses defined by every two neighboring first insulating pillars 316 are formed. At this time, the top surfaces of the first insulating pillars 316 are defined as the top surface of the interlayer insulating layer 210. As illustrated in FIG. 3, each recess can be formed to a depth that is as close as possible to the charge transfer unit 130. As a depth l₁ of a recess is closely connected with a depth of a first spacer 318 in exemplary embodiments of the present invention, it is preferable that the depth l₁ be as large as possible. In other words, a recess may be formed in the interlayer insulating layer 210 such that only a minimum height m₁ for protecting the charge transfer unit 130 remains. However, without being limited to the above example, a recess may extend to the top surface of the semiconductor substrate 101. In addition, a barrier layer and/or an anti-reflective layer may be formed on the semiconductor substrate 101 where the photoelectric converter 110 is formed. Thus, even when a recess extends to the semiconductor substrate 101, the photoelectric converter 110 can be protected. In other words, the depth l₁ of a recess can be appropriately adjusted according to process conditions as long as a device is protected.

A first metal interconnection 312 is formed on the top surfaces of the first insulating pillars 316, i.e., the top surface of the interlayer insulating layer 210. The first metal interconnection 312,including, for example, aluminum (Al), titanium nitride (TiN), titanium (Ti), and copper (Cu) or a multi-layered metal interconnection including, for example, aluminum, titanium nitride, titanium and copper may be used. Both sides of the first metal interconnection 312 are aligned with both sides of each of the first insulating pillars 316. In other words, both sides of the first metal interconnection 312 are aligned with sides of recesses formed adjacent to the first metal interconnection 312. A first mask layer 314 may be formed on the top surface of the first metal interconnection 312.

The first spacer 318 is formed at a side of the first metal interconnection 312 and a side of each of the first insulating pillars 316. In other words, the first spacer 318 is formed at both sides of the first metal interconnection 312 and sides of two recesses aligned with the both sides of the first metal interconnection 312. The first spacer 318 has a smaller refractive index than a first intermetal insulating layer 230 formed on the interlayer insulating layer 210 and a second intermetal insulating layer 250 formed above the first-intermetal insulating layer 230. The first spacer 318 may be an insulating layer, and examples thereof includes, but not limited to, one selected from the group consisting of FLARE, SiLK, fluorinated amorphous silicon (FLAC), fluoro polymer, a porous silica oxide, and combinations thereof.

The first insulating pillar 316, the first metal interconnection 312, and the first spacer 318 constitute a first structure 310, and a plurality of first structures 310 may be formed. The plurality of first structures 310 are spaced a predetermined interval apart from each other in a transverse direction. Each of the plurality of first structures 310 may be formed to surround at least one portion of the circumference of each of the photoelectric converters 110.

On the interlayer insulating layer 210 wherein the first structure 310 is formed, the first intermetal insulating layer 230 is formed to cover the first structure 310. The first intermetal insulating layer 230 may be formed of, for example, silicon oxide, for example, High Density Plasma (HDP), Tonen SilaZene (TOSZ), Spin On Glass (SOG), or Undoped Silica Glass (USG).

A portion of the first intermetal insulating layer 230 protrudes upwardly to form a second insulating pillar 336. The second insulating pillar 336 may be formed aligned with the top surface of the first insulating pillar 316. At this time, a plurality of second insulating pillars 336 protruding above the first intermetal insulating layer 230 are formed, wherein a plurality of recesses defined by every two neighboring second insulating pillars 336 are formed. Herein, the top surfaces of the second insulating pillar 336 are defined as the top surface of the first intermetal insulating layer 230. As illustrated in FIG. 3, each recess can be formed to a depth that is as close as possible to a second metal interconnection 332. As a depth l₂ of a recess is closely connected with a depth of a second spacer 338 in exemplary embodiments of the present invention, it is preferable that the depth l₂ be as long as possible. In other words, a recess may be formed in the first intermetal insulating layer 230 such that only a minimum interval m₂ from the second metal interconnection 332 remains. A second metal interconnection 332 is formed over the top surfaces of the second insulating pillars 336, e.g., the top surface of the first intermetal insulating layer 230. The second metal interconnection 332 including, for example, Al, TiN, Ti, and Cu or a multi-layered metal interconnection including, for example, Al, TiN, Ti, and Cu may be used. Both sides of the second metal interconnection 332 are aligned with both sides of each of the second insulating pillars 336. In other words, both sides of the second metal interconnection 332 are aligned with sides of recesses formed adjacent to the second metal interconnection 332. A second mask layer 334 may be formed on the top surface of the second metal interconnection 332.

The second spacer 338 is formed at a side of the second metal interconnection 332 and a side of each of the second insulating pillars 336. In other words, the second spacer 338 is formed at both sides of the second metal interconnection 332 and sides of two recesses aligned with the both sides of the second metal interconnection 332. The second spacer 338 has a smaller refractive index than the first intermetal insulating layer 230 and the second intermetal insulating layer 250 formed above the first intermetal insulating layer 230. The second spacer 338 may be an insulating layer, and examples thereof includes, but not limited to, one selected from the group consisting of FLARE, SiLK, fluorinated amorphous silicon (FLAC), fluoro polymer, a porous silica oxide, and combinations thereof.

The second insulating pillar 336, the second metal interconnection 332, and the second spacer 338 constitute a second structure 330, and a plurality of second structures 330 may be formed. The plurality of second structures 330 are spaced a predetermined interval apart from each other in a transverse direction. Each of the plurality of second structures 330 may be formed above and aligned with each of the plurality of first structures 310.

On the first intermetal insulating layer 230 where the plurality of second structures 330 are formed, the second intermetal insulating layer 250 may be formed and the top surface thereof may be planarized. Although the first structures 310 and the second structures 330 are aligned vertically in FIG. 3, a multi-layered structure including two or more layers, e.g., an interconnection layer including three or more layers may be formed without being limited to those illustrated in FIG. 3.

A color filter 510 is formed on the first structures 310. For the color filter 510, a color filter, for example, where red, green, and blue are arranged in a Bayer pattern may be used. In the Bayer pattern, a green color filter for green which human eyes are most sensitive to and thus which requires high accuracy occupies a half of the entire color filter 510. However, the arrangement of the color filter 510 may be changed.

Micro lenses 530 are formed in positions corresponding to the photoelectric converters 110 above the color filter 510. The micro lenses 530 may be formed of, for example, a resin of a TMR series and a resin of an MFR series. The micro lenses 530 change the path of a light incident to other regions than the photoelectric converters 110 to collect the incident light to the regions of the photoelectric converters 110.

A planarizing layer 520 may be formed between the color filter 510 and the micro lenses 530 and may be made of, for example, a thermoset resin.

The image sensor according to the current exemplary embodiment of the present invention includes the interlayer insulating layer 210, and the first spacer 318 and the second spacer 338 having smaller refractive indices than the first intermetal insulating layer 230. The first spacer 318 and the second spacer 338 reduce the amount of crosstalk of a light incident through the micro lens 530 towards neighboring photoelectric converters 110.

For example, when a light passes through a different medium, a portion of the light is reflected from a boundary between the medium and the remaining portion of the light penetrates the mediums. In other words, when a light passes through a first medium and a second medium, a portion of the light is reflected from a boundary between the first medium and the second medium and the remaining portion of the light penetrates from the first medium to the second medium. A relationship between refractive indices of the first medium and the second medium and the reflectivity of a light at the boundary between the first medium and the second medium can be expressed as follows:

reflectivity=((n₁−n₂))/(n₁+n₂))

where n₁ represents the refractive index of the first medium and n₂ represents the refractive index of the second medium. As can be seen from this equation, as the difference between the refractive index of the first medium and the refractive index of the second medium increases, the reflectivity of the light at the boundary between the first medium and the second medium may also increase.

Thus, when a light incident to the micro lenses 530 is incident to the first spacer 318 and the second spacer 338 after passing through the interlayer insulating layer 210, the first intermetal insulating layer 230, and the second intermetal insulating layer 250, there may be large differences between refractive indices of the interlayer insulating layer 210, the first intermetal insulating layer 230, and the second intermetal insulating layer 250, and refractive indices of the first spacer 318 and the second spacer 338, thereby resulting in large reflectivity. As a result, the amount of light reflected from boundaries between the interlayer insulating layer 210, the first intermetal insulating layer 230, and the second intermetal insulating layer 250, and the first spacer 318 and the second spacer 338 may increase.

In the current exemplary embodiment of the present invention, the first spacer 318 and the second spacer 338 are formed of materials having smaller refractive indices than the first interlayer insulating layer 210, the first intermetal insulating layer 230, and the second intermetal insulating layer 250, thereby reducing the amount of light incident to neighboring unit pixels, instead of a corresponding unit pixel, and thus reducing crosstalk between pixels.

In the image sensor according to the current exemplary embodiment of the present invention, the first spacer 318 and the second spacer 338 are formed at sides of the first metal interconnection 312 and the second metal interconnection 332 and extend toward the interlayer insulating layer 210 and the first intermetal insulating layer 230 adjacent to the first metal interconnection 312 and the second metal interconnection 332, thereby reducing the amount of crosstalk towards neighboring photoelectric converters 110 through spaces between the first metal interconnection 312 and the second metal interconnection 332.

For example, when only the first metal interconnection 312 and the second metal interconnection 332 serve as a barrier of crosstalk, a light leaks to neighboring pixels through an interval n₁ between the first metal interconnection 312 and the charge transfer unit 130 and an interval n₂ between the first metal interconnection 312 and the second metal interconnection 332. However, when the first spacer 318 and the second spacer 338 are used like in the current exemplary embodiment of the present invention, a light passing through a region corresponding to the height l₁ of the first insulating pillar 316 and the height l₂ of the second insulating pillar 336 is reflected from the first spacer 318 and the second spacer 338. As a result, the light leaks to neighboring pixels only through the interval m₁ between the charge transfer unit 130 and the first structure 310 and the interval m₂ between the first structure 310 and the second structure 330. In other words, the amount of light leaking to neighboring pixels may be significantly reduced. Moreover, if recesses in the interlayer insulating layer 210 and the first intermetal insulating layer 230 are formed to a larger depth, even a small amount of light leaking to neighboring pixels can be shielded.

In other words, according to the current exemplary embodiment of the present invention, it is possible to manufacture an image sensor having improved image reproduction features by reducing crosstalk between pixels.

Hereinafter, a method of manufacturing an image sensor according to an embodiment of the present invention will be described with reference to FIGS. 3 through 10. FIGS. 4 through 10 are views for explaining a method of manufacturing an image sensor according to an exemplary embodiment of the present invention.

Referring to FIG. 4, the photoelectric converters 110 and the interlayer insulating layer 210 are formed on the semiconductor substrate 101.

First, the device isolation regions 102 are formed in the semiconductor substrate 101 to define active regions. Impurities are ion-injected into the active regions to form the photoelectric converters 110, each including the photodiode 112 and the pinning layer 114. Thereafter, transistors corresponding to the charge detector 120, the charge transfer unit 130, the reset unit (140 of FIG. 2), the amplifier (150 of FIG. 2), and the selector (160 of FIG. 2) are formed. Next, the interlayer insulating layer 210 is formed to fill an empty space where the transistors are not formed while covering the entire surface of the semiconductor substrate 101. After the interlayer insulating layer 210 is formed, a process of planarizing the top surface of the interlayer insulating layer 210, e.g., chemical mechanical polishing (CMP), is performed.

Next, referring to FIG. 5, a first metal layer 312a and the first mask layer 314 are formed on the interlayer insulating layer 210.

Here, the first mask layer 314 is formed with a thickness that is sufficiently large for etching the first metal layer 312a and a portion the interlayer insulating layer 210.

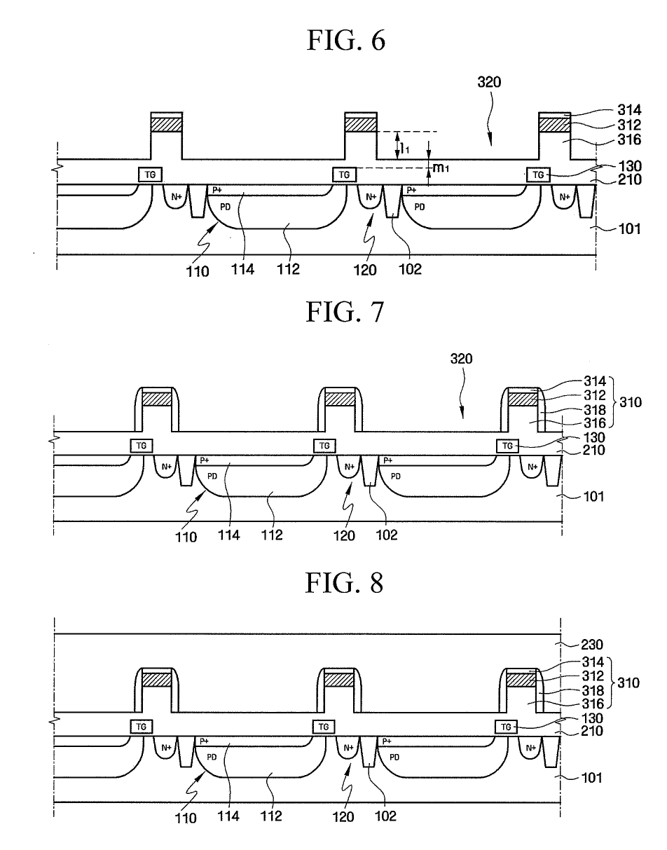

Referring to FIG. 6, the first metal layer (312a of FIG. 5) and a portion of the interlayer insulating layer 210 are etched by using the first mask layer 314 as an etch mask, thereby forming the first metal interconnection 312 and the first insulating pillars 316. At this time, the first mask layer 314 may partially remain.

As the portion of the interlayer insulating layer 210 is etched, the first insulating pillars 316 are formed under the first metal interconnection 312. In other words, the interlayer insulating layer 210 has recesses 320 between neighboring first metal interconnections 312. Namely, the interlayer insulating layer 210 remains to the minimum height m1 for protecting the charge transfer unit 130 and the recesses 320 are formed to a depth above the interlayer insulating layer 210. However, without being limited to the above example, the recesses 320 may be formed extending to the top surfaces of the photoelectric converters 110. In other words, when etch stop layers are formed on the semiconductor substrate 101 and/or the transistors, etching may be performed downward to the top surface of the semiconductor substrate 101. The depth l₁ of the recess 320 of the interlayer insulating layer 210 is equal to the height of each of the first insulating pillars 316 and it is preferable that the depth l₁ be as large as possible. In other words, the depth l₁ of the recess 320 can be appropriately adjusted according to process conditions as long as a device is protected.

Referring to FIG. 7, the first spacer 318 is formed at both sides of the first metal interconnection 312 and at both sides of the first insulating pillars 316.

In other words, the first spacer 318 may be formed at both sides of the first metal interconnection 312 and sides of two recesses aligned with the both sides of the first metal interconnection 312. The first spacer 318 may be formed of a material having a smaller refractive index than the interlayer insulating layer 210 and/or the first intermetal insulating layer 230 and the second intermetal insulating layer 250 to be formed in subsequent processes. Herein, the first metal interconnection 312, the first insulating pillar 316, and the first spacer 318 constitute the first structure 310.

Referring to FIG. 8, the first intermetal insulating layer 230 is formed on the interlayer insulating layer 210 where the plurality of first structures 310 are formed.

The first intermetal insulating layer 230 may be formed of a material having a smaller refractive index than the first spacer 318. After the first intermetal insulating layer 230 is formed, a process of planarizing the top surface of the first intermetal insulating layer 230, e.g., CMP, may be performed.

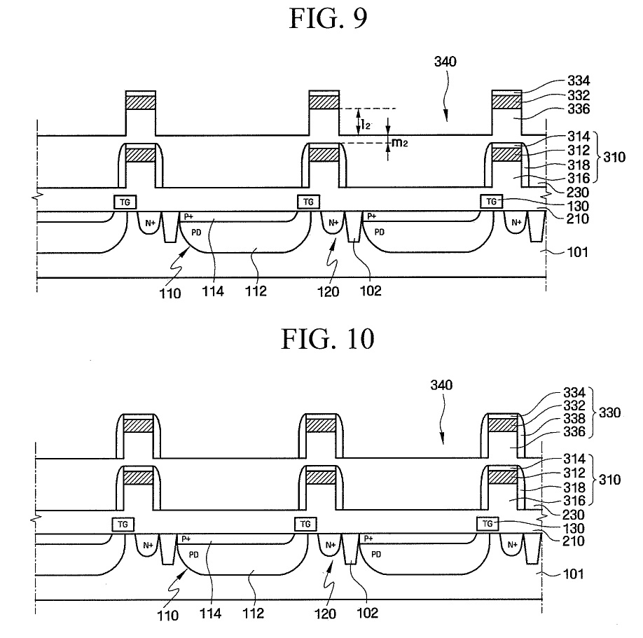

Referring to FIG. 9, the second metal interconnection 332 and the second insulating pillars 336 are formed on the first intermetal insulating layer 230.

For example, once the second metal interconnection 332 is formed and the first intermetal insulating layer 230 exposed between neighboring second metal interconnections 332 is etched to form recesses 340, the second intermetal insulating layer 250 under the second metal interconnection 332 forms the second insulating pillars 336. In other words, the plurality of second insulating pillars 336 protruding above the first intermetal insulating layer 230 are formed, wherein a plurality of recesses 340 defined by every two neighboring second insulating pillars 336 are formed in the first intermetal insulating layer 230. At this time, the top surfaces of the second insulating pillars 336 are defined as the top surface of the first intermetal insulating layer 230. The second insulating pillars 336 are formed aligned with the top surfaces of the first insulating pillars 316, and the recesses 340 may be formed to a depth that is as close as possible to the first structures 310 as illustrated in FIG. 3. As the depth l₂ of the recess 340 is closely connected with a depth of the second spacer 338 in exemplary embodiments of the present invention, it is preferable that the depth l₂ be as long as possible. In other words, the recess 340 may be formed such that only the minimum interval m₂ from the second metal interconnection 332 remains.

Referring to FIG. 10, the second spacer 338 may be formed at both sides of the second metal interconnection 332 and sides of neighboring recesses 340 aligned with the sides of the second metal interconnection 332. The second spacer 338 may be formed of a material having a smaller refractive index than the first intermetal insulating layer and/or the second intermetal insulating layer 250 to be formed in subsequent processes. Herein, the first metal interconnection 312, the first insulating pillar 316, and the first spacer 318 constitute the first structure 310.

Referring back to FIG. 3, the second intermetal insulating layer 250 is formed on the interlayer insulating layer 210 where the plurality of first structures 310 are formed, after which the color filter 510 and the micro lenses 530 are formed on the second intermetal insulating layer 250.

The second intermetal insulating layer 250 is formed of a material having a smaller refractive index than the first spacer 318 on the interlayer insulating layer 210 where the plurality of first structures 310 are formed. After the second intermetal insulating layer 250 is formed, a process of planarizing the top surface of the second intermetal insulating layer 250, e.g., CMP, may be performed.

Next, the color filter 510 is formed on the second intermetal insulating layer 250. The color filter 510 may be arranged such that red, green, and blue are arranged in the Bayer pattern. The planarizing layer 520 may be formed on the color filter 510. The planarizing layer 520 is formed to planarize the top surface where the color filter 510 is formed, and may be formed of, for example, a thermoset resin. To this end, a thermoset resin may be formed by using, for example, spin-on coating and may be hardened with heat, thereby forming the planarizing layer 520. Next, the micro lenses 530 are formed in positions corresponding to the photoelectric converters 110 on the planarizing layer 520.

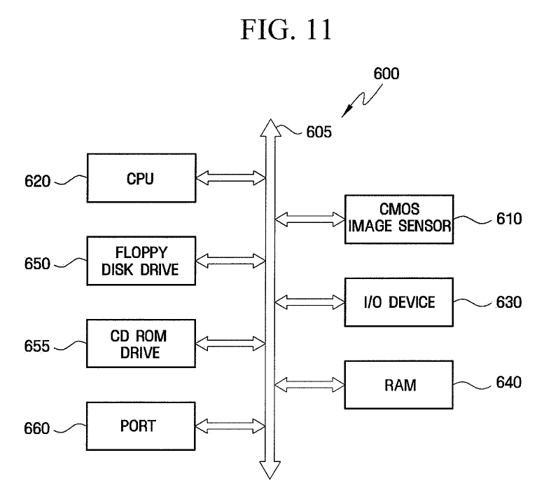

FIG. 11 is a schematic diagram of a processor-based system including an image sensor according to an exemplary embodiment of the present invention.

Referring to FIG. 11, a processor-based system 600 processes an output image of a CMOS image sensor 610. The processor-based system 600 may be, but not limited to, a computer system, a camera system, a scanner, a mechanized clock system, a navigation system, a video phone, a surveillance system, an auto-focus system, a tracking system, a motion monitoring system, and an image stabilizing system.

The processor-based system 600 such as a computer system includes a central processing unit (CPU) 620, such as a microprocessor, capable of communicating with an input/output (I/O) device 630 through a bus 605. The CMOS image sensor 610 can communicate with a system through the bus 605 or other communication links. The processor-based system 600 may further include a random access memory (RAM) 640, a floppy disk drive 650 and/or a compact disc (CD) read-only memory (ROM) drive 655, and a port 660 which are capable of communicating with the CPU 620 through the bus 605. The port 660 may be a port capable of coupling a video card, a sound card, a memory card, and a universal serial bus (USB) device or communicating data with other systems. The CMOS image sensor 610 may be integrated with the CPU 620, a digital signal processor (DSP), or a microprocessor. The CMOS image sensor 610 may also be integrated with a memory. According to circumstances, the CMOS image sensor 610 may be integrated in a different chip than a chip where a processor is integrated.

The image sensor according to exemplary embodiments of the present invention includes the interlayer insulating layer, and the first spacer and the second spacer having smaller refractive indices than the first intermetal insulating layer. The first spacer and the second spacer reduce the amount of crosstalk of a light incident through the micro lens towards neighboring photoelectric converters. In other words, according to exemplary embodiments of the present invention, the first spacer and the second spacer are formed of materials having smaller refractive indices than the first intermetal insulating layer and the second intermetal insulating layer. Therefore, the amount of light incident to neighboring unit pixels, instead of a corresponding unit pixel, can be reduced, thereby reducing crosstalk between pixels.

Moreover, with the image sensor according to exemplary embodiments of the present invention, the first spacer and the second spacer not only are formed at sides of the first metal interconnection and the second metal interconnection but also extend to the interlayer insulating layer and the first intermetal insulating layer that are adjacent to the first metal interconnection and the second metal interconnection, thereby reducing the amount of crosstalk towards neighboring photoelectric converters through spaces between the first metal interconnection and the second metal interconnection.

In other words, according to exemplary embodiments of the present invention, it is possible to manufacture an image sensor having improved image reproduction features by reducing crosstalk between pixels.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. An image sensor comprising:
a photoelectric converter formed in a semiconductor substrate;
an interlayer insulating layer formed on the semiconductor substrate;
a plurality of structures formed on the interlayer insulating layer, each of the plurality of structures including an insulating pillar, a metal interconnection formed on the insulating pillar, and a spacer formed at both sides of the metal interconnection and both sides of the insulating pillar,
wherein the plurality of structures are spaced a predetermined interval apart from each other in a longitudinal direction; and
an intermetal insulating layer filling spaces between the plurality of structures and covering top surfaces of the plurality of structures.

2. The image sensor of claim 1, wherein the spacer has a smaller refractive index than the interlayer insulating layer and the intermetal insulating layer.

3. The image sensor of claim 2, wherein the interlayer insulating layer and the intermetal insulating layer are each silicon oxide layers.

4. The image sensor of claim 2, wherein the spacer is formed of a material selected from the group consisting of FLARE, SiLK, fluorinated amorphous silicon (FLAC), fluoro polymer, a porous silica oxide, and combinations thereof.

5. The image sensor of claim 1, further comprising a micro lens formed on the intermetal insulating layer and positioned to correspond to a top surface of the photoelectric converter.

6. The image sensor of claim 1, wherein each of the plurality of structures surrounds at least a portion of a circumference of the photoelectric converter.

7. The image sensor of claim 1, wherein the insulating pillar is formed by extension of the interlayer insulating layer or the intermetal insulating layer.

8. The image sensor of claim 1, further comprising a mask layer formed on the metal interconnection.

9. An image sensor comprising:
a photoelectric converter formed in a semiconductor substrate;
an interlayer insulating layer formed on the semiconductor substrate;
a plurality of first structures formed on the interlayer insulating layer, each of the plurality of structures including a first insulating pillar protruding above the interlayer insulating layer, a first metal interconnection formed on the first insulating pillar, and a first spacer formed at both sides of the first metal interconnection and both sides of the first insulating pillar,
wherein the plurality of first structures are spaced a predetermined interval apart from each other in a transverse direction;
an intermetal insulating layer formed on the interlayer insulating layer where the plurality of first structures are formed covering the interlayer insulating layer and the plurality of first structures; and
a plurality of second structures formed on the interlayer insulating layer, each of the plurality of second structures including a second insulating pillar protruding above the intermetal insulating layer, a second metal interconnection formed on the second insulating pillar, and a second spacer formed at both sides of the second metal interconnection and both sides of the second insulating pillar, wherein the plurality of second structures spaced a predetermined interval apart from each other in a transverse direction.

10. The image sensor of claim 9, wherein the first and second spacers have smaller refractive indexes than the interlayer insulating layer and the intermetal insulating layer.

11. The image sensor of claim 10, wherein the interlayer insulating layer and the intermetal insulating layer are each silicon oxide layers.

12. The image sensor of claim 10, wherein the first and second spacers are each formed of a material selected from the group consisting of FLARE, SiLK, fluorinated amorphous silicon (FLAC), fluoro polymer, a porous silica oxide, and combinations thereof.

13. The image sensor of claim 9, wherein each of the plurality of first structures or the plurality of second structures surrounds at least one side of a circumference of the photoelectric converter.

14. The image sensor of claim 9, wherein the first insulating pillar is formed by extension of the interlayer insulating layer and the second insulating pillar is formed by extension of the intermetal insulating layer.

15. The image sensor of claim 9, further comprising a first mask layer and a second mask layer formed on the first metal interconnection and the second metal interconnection, respectively.

16. An image sensor comprising:
a plurality of photoelectric converters that are formed adjacent to each other in a semiconductor substrate;
an insulating layer formed on the semiconductor substrate in such a way as to cover the semiconductor substrate, the insulating layer comprising a plurality of recesses formed on at least a portion of each of the plurality of photoelectric converters;
a metal interconnection formed on a top surface of the insulating layer defined between two neighboring recesses of the insulating layer, wherein both sides of the metal interconnection are formed aligned with sides of the two neighboring recesses; and
a spacer formed at both sides of the metal interconnection and sides of the two recesses aligned with the both sides of the metal interconnection.

17. The image sensor of claim 17, wherein the spacer has a smaller refractive index than the insulating layer.

18. The image sensor of claim 18, wherein the insulating layer is a silicon oxide layer.

19. The image sensor of claim 18, wherein the spacer is formed of a material selected from the group consisting of FLARE, SiLK, fluorinated amorphous silicon (FLAC), fluoro polymer, a porous silica oxide, and combinations thereof.

20. The image sensor of claim 17, wherein the metal interconnection is formed between the photoelectric converters formed adjacent to each other.
